(19) United States
(12) Patent Application Publication
(10) Pub. No.: US 2025/0385214 A1
(43) Pub. Date: Dec. 18, 2025

(54) SEMICONDUCTOR PACKAGE

(71) Applicant: SAMSUNG ELECTRONICS CO., LTD., Suwon-si (KR)

(72) Inventors: JONGHO PARK, Suwon-si (KR); Hyun Yang, Suwon-si (KR); Hyunju Lee, Suwon-si (KR); Jaemok Jung, Suwon-si (KR); Ju-Il Choi, Suwon-si (KR); Tae Oh Ha, Suwon-si (KR)

(73) Assignee: SAMSUNG ELECTRONICS CO., LTD., Suwon-si (KR)

(21) Appl. No.: 19/052,956

(22) Filed: Feb. 13, 2025

(30) Foreign Application Priority Data
Jun. 14, 2024 (KR) 10-2024-0077806

(51) Int. Cl. H01L 23/00; H01L 23/538; H01L 25/065

(52) U.S. Cl. CPC H01L 24/49; H01L 24/16; H01L 24/48; H01L 25/0652; H01L 23/5385; H01L 24/13; H01L 24/32; H01L 24/45; H01L 24/73; H01L 24/85; H01L 2224/13147; H01L 2224/16227; H01L 2224/32145; H01L 2224/45124; H01L 2224/45139; H01L 2224/45144; H01L 2224/45147; H01L 2224/48227; H01L 2224/48463; H01L 2224/4903; H01L 2224/49097; H01L 2224/73215; H01L 2224/73253; H01L 2224/73265; H01L 2224/8503; H01L 2224/8518; H01L 2224/85205; H01L 2224/8521; H01L 2225/0651; H01L 2225/06517; H01L 2225/06562; H01L 2924/1815

(57) ABSTRACT

Provided is a semiconductor package including a chip stack that includes first and second semiconductor chips stacked in a first direction and offset in a second direction intersecting the first direction, each of the first and second semiconductor chips comprising chip pads in the second direction, a redistribution substrate on the chip stack, first bonding wires connecting the redistribution substrate and the chip pads of the first semiconductor chip, and first vertical wires connecting the redistribution substrate and the chip pads of the second semiconductor chip. Each of the first bonding wires includes a first portion in contact with one of the chip pads of the first semiconductor chip and having a first width, and a second portion extending perpendicularly on the first portion and having a second width, each of the first vertical wires has a third width, and each of the second and third widths is smaller than the first width.

### CROSS-REFERENCE TO RELATED APPLICATIONS

This application claims priority to Korean Patent Application No. 10-2024-0077806 filed on Jun. 14, 2024, in the Korean Intellectual Property Office, the disclosure of which is incorporated herein in its entirety by reference.

### BACKGROUND

### 1. Field

Embodiments of the present disclosure relate to a semiconductor package.

### 2. Description of Related Art

A semiconductor package is provided to implement an integrated circuit chip to qualify for use in electronic products. A semiconductor package is configured such that a semiconductor chip is mounted on a printed circuit board (PCB) and bonding wires or bumps are used to electrically connect the semiconductor chip to the printed circuit board. With the development of electronic industry, there is a growing interest in standardization and miniaturization of semiconductor packages.

### SUMMARY

One or more embodiments provide a semiconductor package with improved electrical reliability.

One or more embodiments also provide a semiconductor package with improved productivity.

According to an aspect of one or more embodiments, there is provided a semiconductor package including a chip stack including a first semiconductor chip and a second semiconductor chip stacked in a first direction and offset with respect to each other in a second direction intersecting the first direction, each of the first semiconductor chip and the second semiconductor chip including chip pads in the second direction, a redistribution substrate on the chip stack, first bonding wires connecting the redistribution substrate and the chip pads included in the first semiconductor chip, and first vertical wires connecting the redistribution substrate and the chip pads included in the second semiconductor chip, wherein each first bonding wire of the first bonding wires including a first portion in contact with one of the chip pads included in the first semiconductor chip and having a first width, and a second portion on the first portion extending in the first direction and having a second width, wherein each first vertical wire of the first vertical wires has a third width, and wherein the second width and the third width are smaller than the first width.

According to another aspect of one or more embodiments, there is provided a semiconductor package including a chip stack including a plurality of semiconductor chips stacked in a first direction and offset from each other in a second direction intersecting the first direction, a first semiconductor chip included in the plurality of semiconductor chips including first chip pads and second chip pads alternately in the second direction, a redistribution substrate on the chip stack, first bonding wires connecting the first chip pads included in the first semiconductor chip and the redistribution substrate, and first vertical wires connecting the second chip pads included in the first semiconductor chip and the redistribution substrate, wherein each first bonding wire of the first bonding wires includes a first portion in contact with one of the first chip pads included in the first semiconductor chip and having a first width, and a second portion on the first portion extending in the first direction and having a second width, wherein each of the first vertical wires has a third width, and wherein the second width and the third width are each smaller than the first width.

According to still another aspect of one or more embodiments, there is provided a semiconductor package including a chip stack including a first semiconductor chip, a second semiconductor chip, a third semiconductor chip, and a fourth semiconductor chip stacked in a first direction and offset with respect to each other in a second direction intersecting the first direction, each of the first semiconductor chip, the second semiconductor chip, the third semiconductor chip, and the fourth semiconductor chip including chip pads in the second direction intersecting, a molding layer on the chip stack, a redistribution substrate on the chip stack and the molding layer, first bonding wires connecting the redistribution substrate and the chip pads included in the first semiconductor chip, first vertical wires connecting the redistribution substrate and the chip pads included in the second semiconductor chip, a second bonding wire connecting the redistribution substrate and a first chip pad among the chip pads included in the third semiconductor chip, a second vertical wire connecting the redistribution substrate and a second chip pad adjacent to the first chip pad in the second direction among the chip pads included in the third semiconductor chip, and a chip bump connecting the redistribution substrate and the fourth semiconductor chip, wherein each of the first bonding wires includes a first portion in contact with one of the chip pads of the first semiconductor chip and having a first width, and a second portion on the first portion extending in the first direction and having a second width, wherein each of the first vertical wires has a third width, and wherein the second width and the third width are smaller than the first width.

### BRIEF DESCRIPTION OF DRAWINGS

Embodiments will be more clearly understood from the following brief description taken in conjunction with the accompanying drawings. The accompanying drawings represent non-limiting, example embodiments as described herein, in which:

FIG. 1 is a plan view of a semiconductor package according to one or more embodiments;

FIGS. 2A, 2B, 2C, and 2D are cross-sectional views taken along lines A-A′, B-B′, C-C′, and D-D′ of FIG. 1, respectively;

FIGS. 3A and 3B are enlarged views of ‘P1’ and ‘P2’ in FIG. 2A, respectively;

FIG. 3C is an enlarged view of ‘P3’ in FIG. 2D;

FIG. 4 is a plan view of a semiconductor package according to one or more other embodiments;

FIGS. 5A, 5B, and 5C are cross-sectional views taken along lines A-A′, D-D′, and E-E′ of FIG. 4, respectively;

FIG. 6 is an enlarged view of ‘P2’ in FIG. 5A;

FIGS. 7, 8, 9, 10A, 10B, 11A, and 11B are plan views and cross-sectional views illustrating a method of manufacturing a semiconductor package according to one or more embodiments; and

FIG. 12 is a cross-sectional view illustrating a semiconductor package according to one or more embodiments.

### DETAILED DESCRIPTION

Hereinafter, to explain the inventive concept in more detail, embodiments according will be described with reference to the accompanying drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

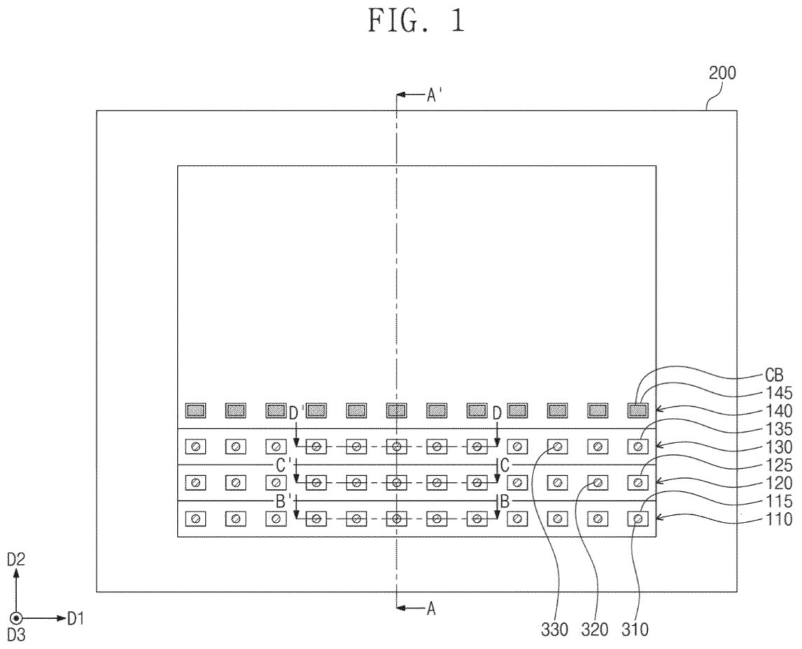

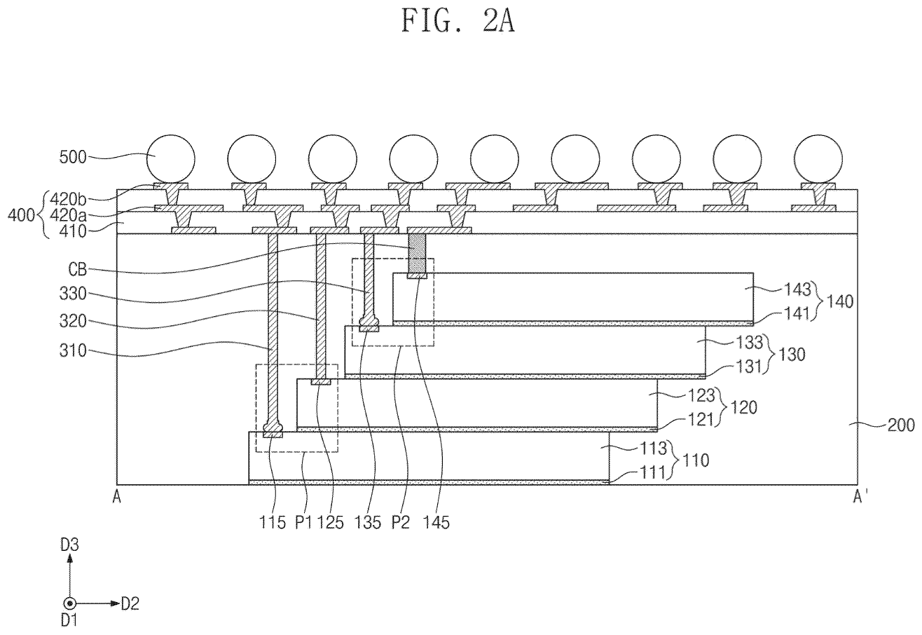

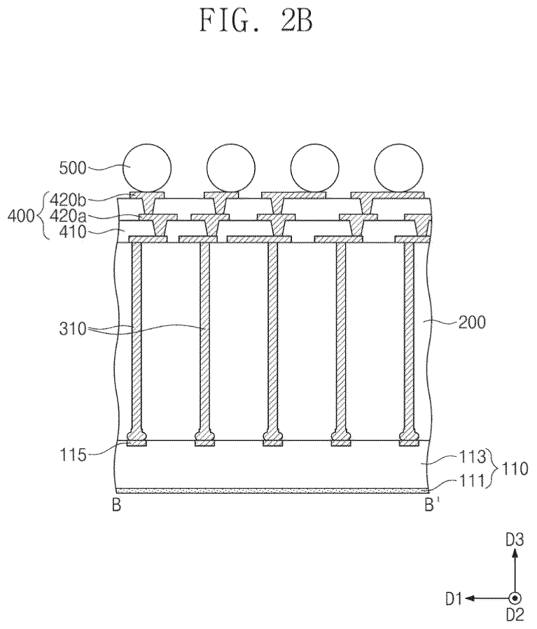

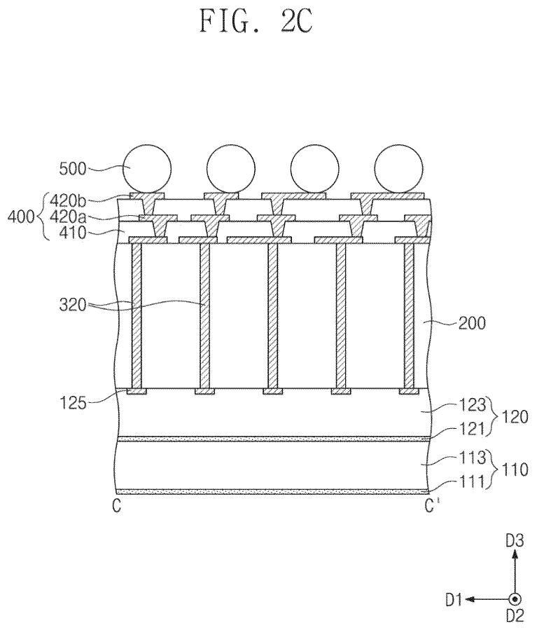

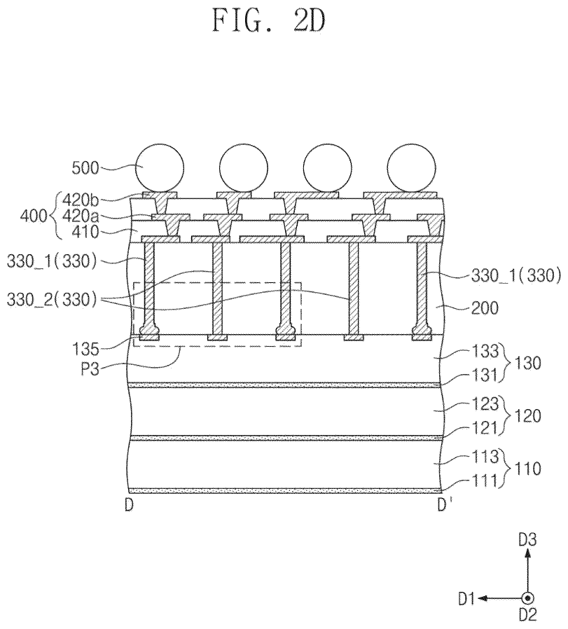

FIG. 1 is a plan view of a semiconductor package according to one or more embodiments. FIGS. 2A to 2D are cross-sectional views taken along lines A-A′, B-B′, C-C′, and D-D′ of FIG. 1, respectively.

Referring to FIGS. 1 and 2A to 2D, a semiconductor package may include a chip stack 110, 120, 130, and 140, a molding layer 200, a plurality of bonding wires and vertical wires 310, 320, and 330, and a redistribution substrate 400.

The chip stack 110, 120, 130, and 140 may include a first semiconductor chip 110, a second semiconductor chip 120, a third semiconductor chip 130, and a fourth semiconductor chip 140. The first to fourth semiconductor chips 110, 120, 130, and 140 may include die adhesive layers 111, 121, 131, and 141 and semiconductor dies 113, 123, 133, and 143, respectively. For example, the first semiconductor chip 110 may include a first die adhesive layer 111 and a first semiconductor die 113, and the second semiconductor chip 120 may include a second die adhesive layer 121 and a second semiconductor die 123. Similarly, the third semiconductor chip 130 may include a third die adhesion layer 131 and a third semiconductor die 133, and the fourth semiconductor chip 140 may include a fourth die adhesion layer 141 and a fourth semiconductor die 143. The first to fourth die adhesive layers 111, 121, 131, and 141 may be disposed on lower surfaces of the first to fourth semiconductor dies 113, 123, 133, and 143, respectively. As an example, the first to fourth die adhesive layers 111, 121, 131, and 141 may include an insulating adhesive material. Memory devices may be integrated into the first to fourth semiconductor dies 113, 123, 133, and 143. Hereinafter, the description is based on four semiconductor chips, but the number of semiconductor chips may be more or less, and is not limited thereto.

The first to fourth semiconductor chips 110, 120, 130, and 140 may be sequentially stacked in a stair-step manner in a second direction D2. For example, the second semiconductor chip 120 may be stacked on the first semiconductor chip 110 with an offset in the second direction D2, the third semiconductor chip 130 may be stacked on the second semiconductor chip 120 with an offset in the second direction D2, and the fourth semiconductor chip 140 may be stacked on the third semiconductor chip 130 with an offset in the second direction D2.

The first to fourth semiconductor chips 110, 120, 130, and 140 may include chip pads 115, 125, 135, and 145, respectively. The chip pads 115 may be disposed on a portion of an upper surface of the first semiconductor chip 110 that does not overlap the second semiconductor chip 120. Similarly, the chip pad 125 may be disposed on a portion of an upper surface of the semiconductor chip 120 that does not overlap the third and fourth semiconductor chips 130 and 140. The chip pads 135 may be disposed on a portion of an upper surface of the third semiconductor chip 130 that does not overlap the fourth semiconductor chip 140. The chip pads 145 may be disposed on an upper surface of the fourth semiconductor chip 140. A plurality of chip pads 115, 125, 135, and 145 may be provided in each of the semiconductor chips 110, 120, 130, and 140, and may be spaced apart in a first direction D1.

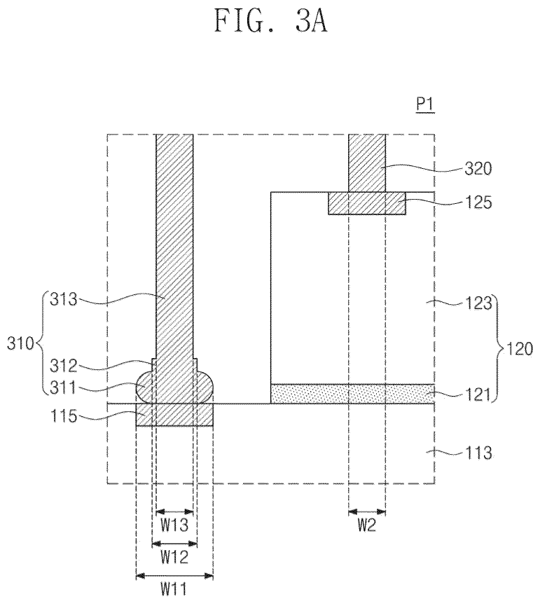

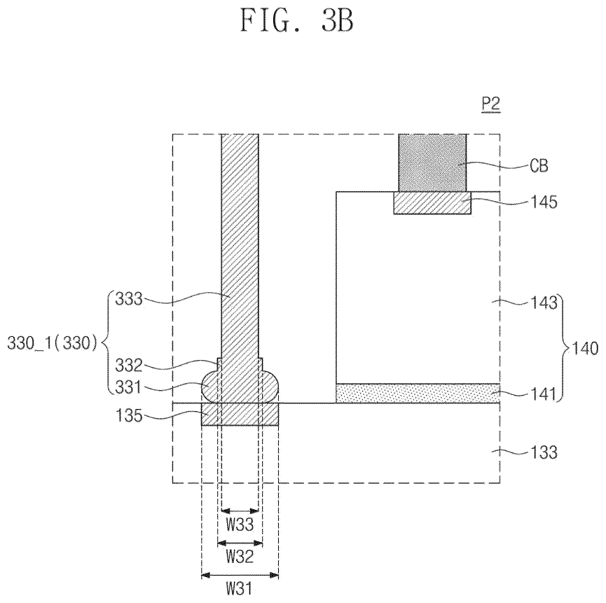

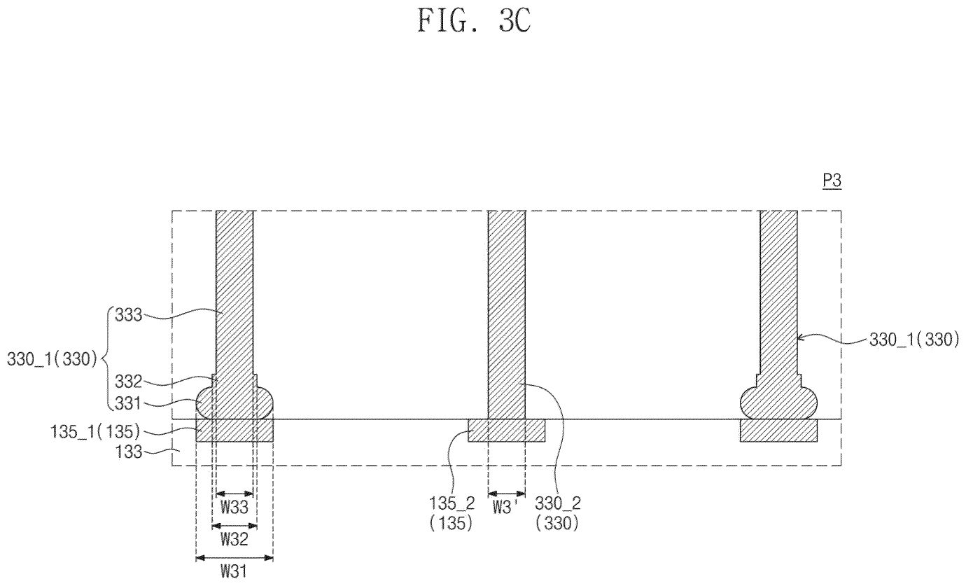

A plurality of bonding wires and vertical wires 310, 320, and 330 may connect the chip stack 110, 120, 130, and 140 and the redistribution substrate 400 to be described later. As an example, the first bonding wires 310 may connect the chip pads 115 of the first semiconductor chip 110 and the redistribution substrate 400, respectively, and the first vertical wires 320 may connect the chip pads 125 of the second semiconductor chip 120 and the redistribution substrate 400, respectively. The second bonding wires 330_1 and the second vertical wires 330_2 may connect the chip pads 135 of the third semiconductor chip 130 and the redistribution substrate 400, respectively (refer to FIG. 2D). The first and second bonding wires 310 and 330_1 may be wires that are ball-bonded to the chip pads 115, 125, 135, and 145, and the first and second vertical wires 320 and 330_2 may be wires that are stitch-bonded to the chip pads 115, 125, 135, and 145. The plurality of bonding wires and vertical wires 310, 320, and 330 will be described in detail later with reference to FIGS. 3A to 3C.

The molding layer 200 may cover the chip stack 110, 120, 130, and 140. The molding layer 200 may cover upper surfaces and side surfaces of the chip stack 110, 120, 130, and 140. The molding layer 200 may cover side surfaces of the plurality of bonding wires and the vertical wires 310, 320, and 330. An upper surface of the molding layer 200 may be substantially coplanar with upper surfaces of the plurality of bonding wires and the vertical wires 310, 320, and 330. As an example, the molding layer 200 may include a material such as, for example, an epoxy molding compound or an adhesive material.

The redistribution substrate 400 may include an insulating layer 410 and redistribution patterns 420a and 420b. The redistribution patterns 420a and 420b may be electrically connected to the plurality of bonding wires and vertical wires 310, 320, and 330. A portion of the redistribution patterns 420a and 420b may be disposed in the insulating layer 410, and the uppermost redistribution pattern 420b may partially penetrate the insulating layer 410, and may protrude above the insulating layer 410.

A package connection terminal 500 may be additionally disposed on the redistribution substrate 400. The package connection terminal 500 may be connected to the uppermost redistribution pattern 420b. As an example, the package connection terminal 500 may include tin (Sn), bismuth (Bi), lead (Pb), silver (Ag), or an alloy thereof. The package connection terminal 500 may have a solder ball shape.

Referring to FIGS. 2A to 3C, the plurality of bonding wires and vertical wires 310, 320, and 330 will be described in detail. FIGS. 3A and 3B are enlarged views of ‘P1’ and ‘P2’ in FIG. 2A, respectively. FIG. 3C is an enlarged view of ‘P3’ in FIG. 2D.

Referring to FIGS. 2A, 2B, and 3A, first bonding wires 310 may be disposed on chip pads 115 of the first semiconductor chip 110. The first bonding wires 310 may be spaced apart in the first direction D1 on the chip pads 115 of the first semiconductor chip 110. One end of the first bonding wire 310 may be in contact with the chip pad 115 of the first semiconductor chip 110, and the other end of the first bonding wire 310 may be in contact with the redistribution pattern 420a of the redistribution substrate 400.

Referring to FIGS. 2A and 3A in more detail, the first bonding wire 310 may include a first portion 311 in contact with the chip pad 115 of the first semiconductor chip 110, a third portion 313 extending vertically in the third direction D3 on the first portion 311, and a second portion 312 between the first portion 311 and the third portion 313. The third portion 313 may extend vertically and may be in contact with the redistribution substrate 400. For example, an upper surface of the third portion 313 of the first bonding wire 310 may be coplanar with an upper surface of the first vertical wire 320. A vertical length of the third portion 313 may be greater than a vertical length of the first portion 311 and a vertical length of the second portion 312. A vertical length of the first to third portions 311, 312, and 313 may be a length in the third direction D3.

The first to third portions 311, 312, and 313 of the first bonding wire 310 may have first and third widths W11, W12, and W13 in a direction parallel to the upper surface of the first semiconductor chip 110 (e.g., the first direction D1 or the second direction D2), respectively. The first width W11 may be greater than the third width W13. The second width W12 may be greater than the third width W13 and may be smaller than the first width W11.

The first portion 311 of the first bonding wire 310 may have a shape of a sphere or a sphere compressed vertically. When viewed in a plan view, the first to third portions 311, 312, and 313 of the first bonding wire 310 may have a circular shape. When viewed in a cross-sectional view, the first portion 311 of the first bonding wire 310 may have a rounded sidewall, and the second portion 312 and the third portion 313 of the first bonding wire 310 may have a straight sidewall. According to one or more embodiments, the second portion 312 may be omitted from the first bonding wire 310, and the first portion 311 and the third portion 313 may be connected directly. The shape of the first portion 311 and the third portion 313 of the first bonding wire 310 may be profiles obtained by ball bonding the wire to the chip pad 115 of the first semiconductor chip 110.

Referring again to FIGS. 2A and 2C, the first vertical wires 320 may be disposed on the chip pads 125 of the second semiconductor chip 120. The first vertical wires 320 may be spaced apart in the first direction D1 on the chip pads 125 of the second semiconductor chip 120. One end of the first vertical wire 320 may be in contact with the chip pad 125 of the second semiconductor chip 120, and the other end of the first vertical wire 320 may be in contact with the redistribution pattern 420a of the redistribution substrate 400. A vertical length of the first vertical wire 320 may be smaller than a vertical length of the first bonding wire 310. A length of the first bonding wire 310 may be a distance in the third direction D3 from the uppermost first bonding wire 310 to the lowermost the first portion 311.

The first vertical wire 320 has a uniform width and may extend vertically in the third direction D3. Referring to FIGS. 2A and 3A, the first vertical wire 320 may have a fourth width W2 in a direction parallel to an upper surface of the second semiconductor chip 120 (e.g., the first direction D1 or the second direction D2). The fourth width W2 may be smaller than first width W11 and the second width W12, and may be substantially equal to the third width W13, which are described above. A shape of the first vertical wire 320 may be obtained by stitch bonding the wire to the chip pad 125 of the second semiconductor chip 120. In FIGS. 1 to 3A, the first bonding wires 310 may be disposed on the chip pads 115 of the first semiconductor chip 110, and the first vertical wires 320 may be disposed on the chip pads 125 of the second semiconductor chip 120, but embodiments are not limited thereto. For example, first vertical wires 320 may be disposed on the chip pads 115 of the first semiconductor chip 110, and first bonding wires 310 may be disposed on the chip pads 125 of the second semiconductor chip 120.

Referring again to FIGS. 2A, 2D, 3B, and 3C, the second bonding wires 330_1 and the second vertical wires 330_2 may be disposed on the chip pads 135 of the third semiconductor chip 130. The second bonding wires 330_1 and the second vertical wires 330_2 may be spaced apart from each other in the first direction D1 and may be arranged alternately with each other. For convenience of explanation, the chip pad 135 of the third semiconductor chip 130 in contact with the second bonding wire 330_1 is referred to as the first chip 135_1, and the chip pad 135 of the semiconductor chip 130 in contact with the second vertical wire 330_2 is referred to as the second chip pad 135_2.

The second bonding wires 330_1 may be disposed on the first chip pads 135_1 of the third semiconductor chip 130, and the second vertical wires 330_2 may be disposed on the second chip pads 135_2 of the third semiconductor chip 130. The first chip pads 135_1 and the second chip pads 135_2 may be alternately arranged and spaced apart in the first direction D1. A vertical length of the second bonding wire 330_1 may be substantially the same as a vertical length of the second vertical wire 330_2. As an example, a vertical length of the second bonding wire 330_1 may be a distance in the third direction D3 from the uppermost of the second bonding wire 330_1 to the lowermost of the second bonding wire 330_1.

Each of the second bonding wires 330_1 may have a similar shape to a shape of the first bonding wire 310 described above. For example, the second bonding wire 330_1 may include a fourth portion 331 in contact with the chip pad 135 of the third semiconductor chip 130, a sixth portion 333 extending vertically in the third direction D3 on the fourth portion 331, and a fifth portion 332 between the fourth portion 331 and the sixth portion 333. An upper surface of the sixth portion 333 of the second bonding wire 330_1 may be coplanar with an upper surface of the second vertical wire 330_2.

The fourth to sixth portions 331, 332, and 333 of the second bonding wire 330_1 may have fifth to seventh widths W31, W32, and W33 in a direction parallel to an upper surface of the third semiconductor chip 130 (e.g., in the first direction D1 or in the second direction D2), respectively. The fifth width W31 may be greater than the seventh width W33. The sixth width W32 may be greater than the seventh width W33 and may be smaller than the fifth width W31.

The fourth portion 331 of the second bonding wire 330_1 may have a shape of a sphere or a sphere compressed vertically. When viewed in a plan view, the fourth to sixth portions 331, 332, and 333 of the second bonding wire 330_1 may have a circular shape. When viewed in a cross-sectional view, the fourth portion 331 of the second bonding wire 330_1 may have a rounded sidewall, and the second portion 332 and the third portion 333 of the second bonding wire 330_1 may have a straight sidewall. Shapes of the fourth portion 331 and the sixth portion 333 of the second bonding wire 330_1 may be obtained by ball bonding the wire to the first chip pad 135_1 of the third semiconductor chip 130.

Each of the second vertical wires 330_2 may have a similar shape to a shape of the first vertical wire 320 described above. The second vertical wire 330_2 has a uniform width and may extend vertically in the third direction D3. The second vertical wire 330_2 may have an eighth width W3′ in a direction parallel to the upper surface of the third semiconductor chip 130 (e.g., the first direction D1 or the second direction D2). The eighth width W3′ may be smaller than the aforementioned fifth width W31 and sixth width W32, and may be substantially equal to the seventh width W33. A shape of the second vertical wire 330_2 may be obtained by stitch bonding the wire to the second chip pad 135_2 of the third semiconductor chip 130.

Referring again to FIG. 2A, chip bumps CB may be disposed on the fourth semiconductor chip 140. The chip bump CB may be in contact with the chip pad 145 of the fourth semiconductor chip 140. The chip bump CB may electrically connect the chip pad 145 of the fourth semiconductor chip 140 and the redistribution substrate 400.

The molding layer 200 may cover the chip stack 110, 120, 130, and 140, the first and second bonding wires 310 and 330_1, the first and second vertical wires 320 and 330_2, and the chip bump CB. The molding layer 200 may cover side surfaces of the first and second bonding wires 310 and 330_1, the first and second vertical wires 320 and 330_2, and the chip bump CB. An upper surface of the molding layer 200 may be coplanar with upper surfaces of the first and second bonding wires 310 and 330_1, upper surfaces of the first and second vertical wires 320 and 330_2, and an upper surface of the chip bump CB.

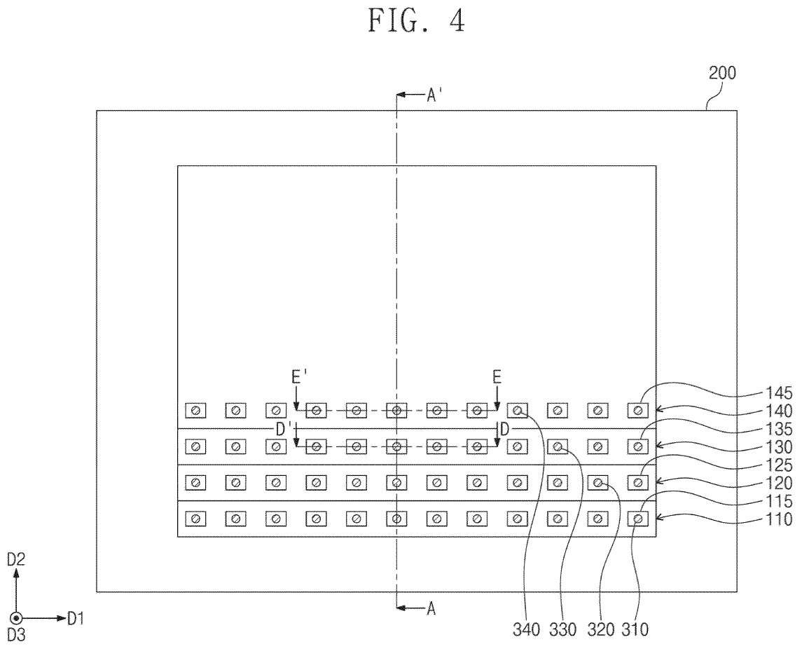

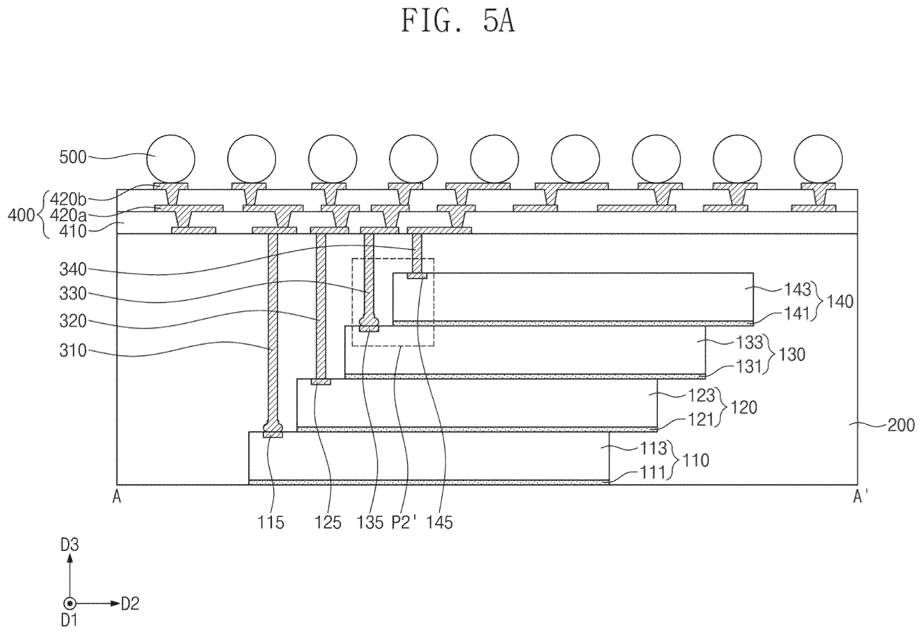

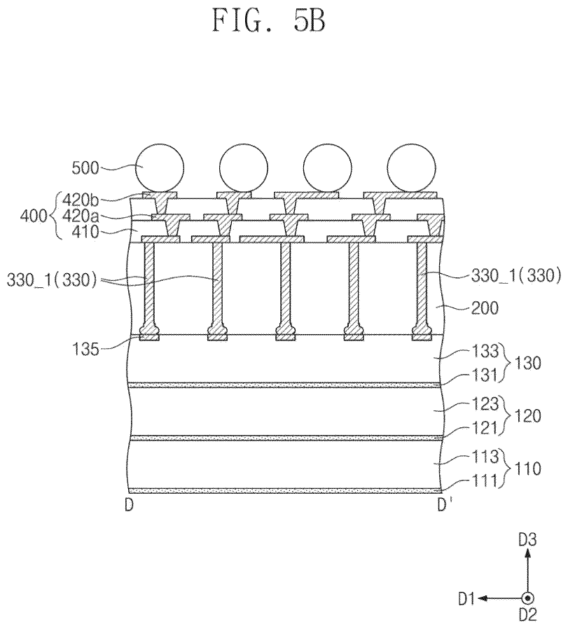

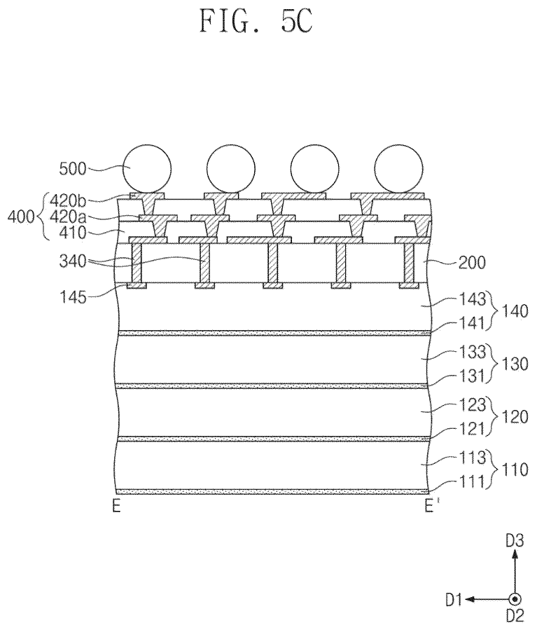

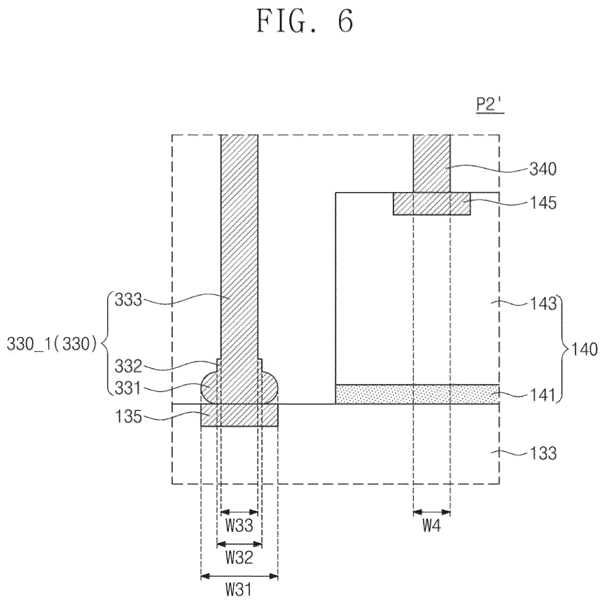

FIG. 4 is a plan view of a semiconductor package according to one or more other embodiments. FIGS. 5A to 5C are cross-sectional views taken along lines A-A′, D-D′, and E-E′ of FIG. 4, respectively. FIG. 6 is an enlarged view of ‘P2’ in FIG. 5A. In the one or more other embodiments to be described later, detailed descriptions of technical features overlapping with those previously described with reference to FIGS. 1 to 3C will be omitted, and differences will be described in detail.

Referring to FIGS. 4 and 5A to 5C, the second bonding wires 330 may connect the redistribution substrate 400 and the chip pads 135 of the third semiconductor chip 130. The second bonding wires 330 may be disposed on the chip pads 135 of the third semiconductor chip 130, respectively, and may be spaced apart from each other in the first direction D1.

The second vertical wires 340 may connect the redistribution substrate 400 and the chip pads 145 of the fourth semiconductor chip 140. The second vertical wires 340 may be disposed on the chip pads 145 of the fourth semiconductor chip 140, respectively, and may extend vertically in the third direction D3. The second vertical wires 340 may be spaced apart from each other in the first direction D1. A vertical length of the second vertical wire 340 may be smaller than a vertical length of the second bonding wire 330. A vertical length of the second bonding wire 330 may be a distance from the uppermost of the second bonding wire 300 and the lowermost of the second bonding wire 330 in the third direction D3.

Referring to FIGS. 5A and 6, the second bonding wire 330 may have the same shape as the second bonding wire 330_2 (e.g., in FIG. 3C) of the embodiment described above in FIGS. 1 to 3C. For example, the second bonding wire 330 may include a fourth portion 331 in contact with the chip pad 135 of the third semiconductor chip 130, a sixth portion 333 extending vertically in the third direction D3 on the fourth portion 331, and a fifth portion 332 between the fourth portion 331 and the sixth portion 333.

The fourth to sixth portions 331, 332, and 333 of the second bonding wire 330 may have fifth to seventh widths W31, W32, and W33 in a direction parallel to the upper surface of the third semiconductor chip 130 (e.g., the first direction D1 or the second direction D2), respectively. The fifth width W31 may be greater than the seventh width W33. The sixth width W32 may be greater than the seventh width W33 and may be smaller than the fifth width W31.

The second vertical wire 340 may have a uniform width and may extend vertically in the third direction D3. The second vertical wire 340 may have a ninth width W4 in a direction parallel to an upper surface of the fourth semiconductor chip 140 (e.g., the first direction D1 or the second direction D2). The ninth width W4 may be smaller than the aforementioned fifth width W31 and sixth width W32, and may be substantially equal to the seventh width W33. A shape of the second vertical wire 340 may be obtained by stitch bonding the wire to the chip pad 145 of the fourth semiconductor chip 140.

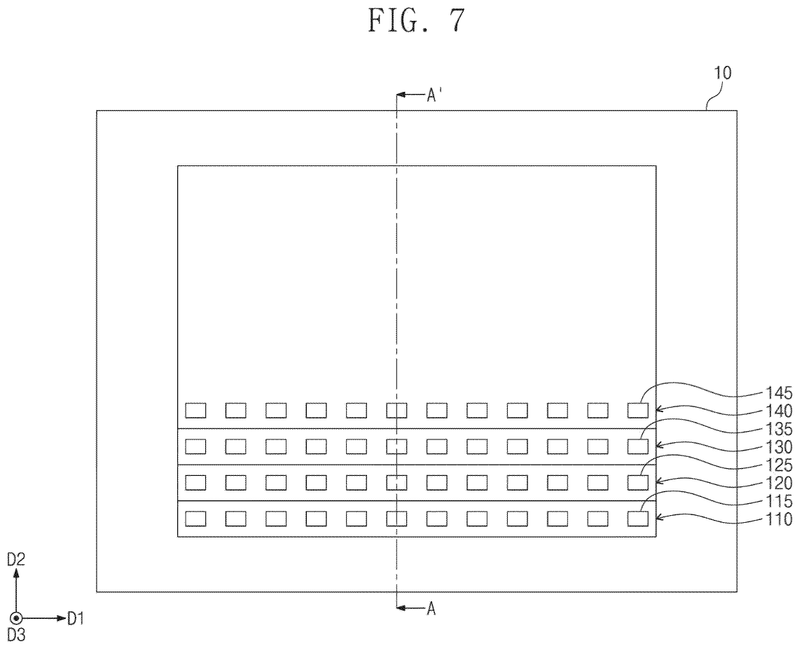

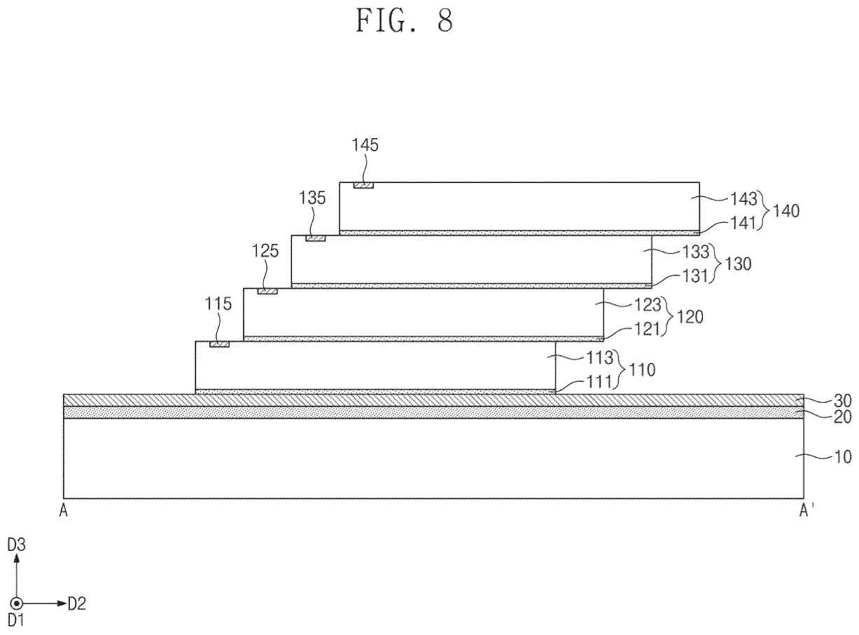

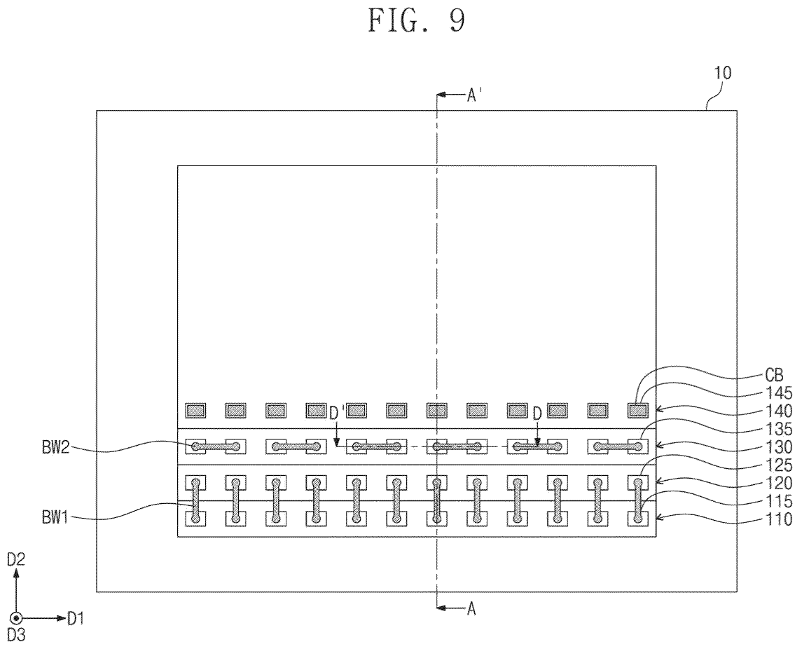

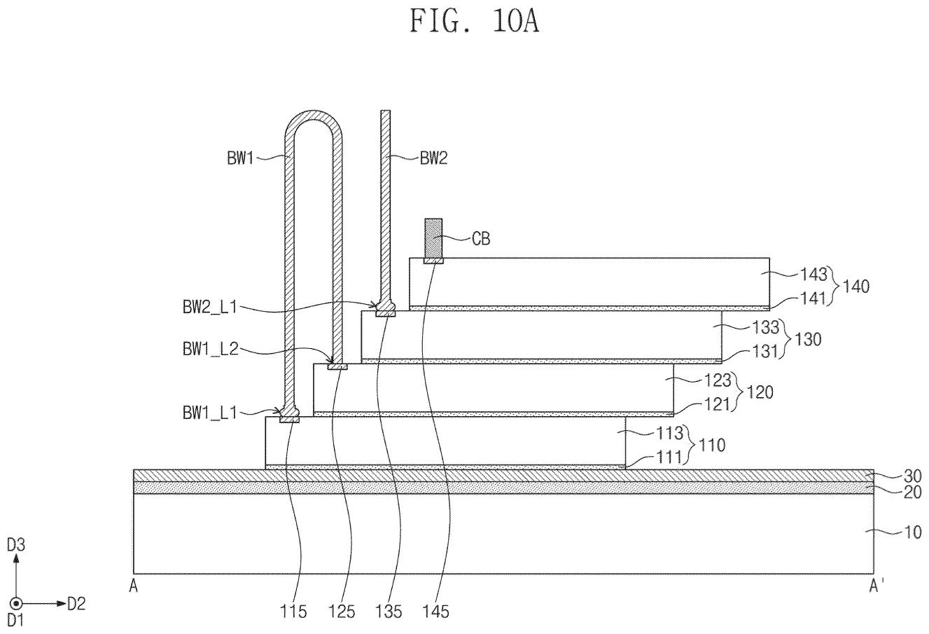

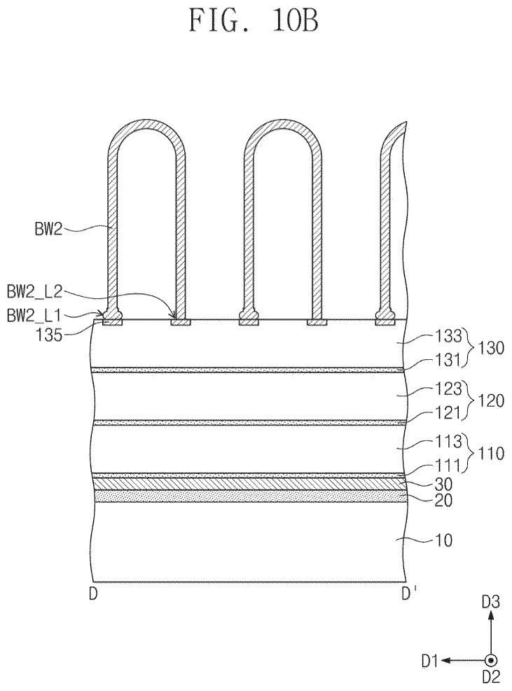

FIGS. 7 to 11B are plan views and cross-sectional views illustrating a method of manufacturing a semiconductor package according to one or more embodiments. FIG. 8 is a cross-sectional view taken along line A-A′ of FIG. 7, and FIGS. 10A and 10B are cross-sectional views taken along line A-A′ and line D-D′ of FIG. 9.

Referring to FIGS. 7 and 8, a carrier substrate 10 having an adhesive layer 20 formed on one surface may be provided. A metal layer 30 may be formed on the carrier substrate 10 to cover the adhesive layer 20. The metal layer 30 may be formed through a deposition process. As an example, the metal layer 30 may include copper (Cu) or titanium (Ti), and the adhesive layer 20 may include at least one of polypropylene, polyimide, polyvinyl alcohol, and polyvinylidene fluoride, but embodiments are not limited thereto.

A chip stack 110, 120, 130, and 140 may be stacked on the metal layer 30. Stacking the chip stack 110, 120, 130, and 140 may include stacking a first semiconductor chip 110 on the metal layer 30, stacking a second semiconductor chip 120 on the first semiconductor chip 110, stacking a third semiconductor chip 130 on the second semiconductor chip 120, and stacking a fourth semiconductor chip 140 on the third semiconductor chip 130. The first to fourth semiconductor chips 110, 120, 130, and 140 may be attached on the carrier substrate 10 by the die adhesive layers 111, 121, 131, and 141 disposed on lower surfaces thereof, respectively.

The first to fourth semiconductor chips 110, 120, 130, and 140 may be stacked in steps in the second direction D2, and during the stacking process, the first to third semiconductor chips 110, 120, and 130 may be sequentially deposited. An upper surface of the first to fourth semiconductor chips 110, 120, 130, and 140 may be partially exposed. Furthermore, chip pads 115, 125, and 135 of the first through third semiconductor chips 110, 120, and 130 may be exposed through the exposed upper surfaces of the first through third semiconductor chips 110, 120, and 130.

Referring to FIGS. 9, 10A, and 10B, chip bumps CB may be formed on the chip pads 145 of the fourth semiconductor chip 140. An additional wire may not be formed on the chip bump CB. The chip bump CB may be formed through a typical bump forming process. As an example, the chip bump may include copper (Cu).

A first wire BW1 may be formed on the chip pads 115 and 125 of the first and second semiconductor chips 110 and 120 through a first wire bonding process. As an example, the first wire bonding process may be performed by moving a capillary. For example, the first wire bonding process may include melting a wire drawn from a capillary on the chip pad 115 of the first semiconductor chip 110 to form a wire ball, moving the capillary from the chip pad 115 of the first semiconductor chip 110 to the first semiconductor chip of the second semiconductor chip 120 to extract the wire connected to the wire ball, cutting the wire on the chip pad 125 of the second semiconductor chip 120, and attaching an end of the wire to the chip pad 125 of the second semiconductor chip 120. For example, the wire drawn from the capillary may include one of gold (Au), silver (Ag), copper (Cu), and aluminum (Al).

The attaching of the wire ball to the chip pad 115 of the first semiconductor chip 110 may be performed, for example, by applying heat and/or ultrasonic energy, and the wire ball and the chip pad 115 of the first semiconductor chip 110 may be ball-bonded.

The extracting of the wire may include moving the capillary in a vertical direction (e.g., the third direction D3) to draw out the wire connected to the wire ball after attaching the wire ball to the chip pad 115 of the first semiconductor chip 110, moving the capillary in the second direction D2 onto the second semiconductor chip 120 to extend the wire, and lowering the capillary in a vertical direction to extend wire. After vertically moving the capillary on the first semiconductor chip 110, moving the capillary in the second direction D2 onto the second semiconductor chip 120 may move in a curve, for example, may move along an inverted U-shape.

The attaching of the end of the wire to the chip pad 125 of the second semiconductor chip 120 may be performed by applying heat and/or ultrasonic energy. The end of the wire and the chip pad 125 of the second semiconductor chip 120 may be stitch-bonded.

One end BW1_L1 of the first wire BW1 may be in contact with the chip pad 115 of the first semiconductor chip 110. For example, the one end BW1_L1 of the first wire BW1 may have the shape of a round ball, obtained by performing ball bonding. The other end BW1_L2 of the first wire BW1 may be in contact with the chip pad 125 of the second semiconductor chip 120. For example, the other end BW1_L2 of the first wire BW1 may be formed to have a substantially uniform width and may have a smaller width than the one end BW1_L1 of the first wire BW1, obtained by performing stitch bonding on the other end BW1_L2 of the first wire BW1.

Both ends BW1_L1, BW1_L2 of the first wire BW1 may be formed to be in vertical contact with the chip pad 115 of the first semiconductor chip 110 and the chip pad 125 of the second semiconductor chip 120, respectively. The first wire BW1 may extend vertically in the third direction D3 without being inclined at both ends BW1_L1 and BW1_L2, and may have a curved shape at an upper portion thereof. For example, when viewed in a cross-sectional view, the first wire BW1 has an inverted U-shape, and lower ends of both sides may be connected to the chip pad 115 of the first semiconductor chip 110 and the chip pad 125 of the second semiconductor chip 120, respectively.

A second wire bonding process may be performed on the third semiconductor chip 130 to connect the chip pads 135 adjacent to each other in the first direction D1. The second wire bonding process may be performed on the third semiconductor chip 130, and a second wire BW2 may be formed to connect the chip pads 135 adjacent to each other in the first direction through the second wire bonding process. For convenience of explanation, among the chip pads 135 of the third semiconductor chip 130, two chip pads 135 adjacent to each other in the first direction D1 will be referred to as the first chip pad 135 and the second chip pad 135.

As an example, the second wire bonding process may be performed by moving the capillary. For example, the second wire bonding process may include melting a wire drawn from the capillary on the first chip pad 135 of the third semiconductor chip 130 to form a wire ball, moving the capillary from the first chip pad 135 of the third semiconductor chip 130 to the second chip pad 135 adjacent to the first chip pad 135 of the third semiconductor chip 130 in the first direction D1 to extract the wire connected to the wire ball, cutting the wire on the second chip pad 135 of the third semiconductor chip 130, and attaching an end of the wire and the second chip pad 135 of the third semiconductor chip 130.

The attaching of the wire ball to the first chip pad 135 of the third semiconductor chip 130 may be performed, for example, by applying heat and/or ultrasonic energy, and the wire ball and the chip pad 135 of the third semiconductor chip 130 may be ball-bonded.

The extracting of the wire may include attaching the wire ball to the first chip pad 135 of the third semiconductor chip 130 and then moving the capillary in the vertical direction (e.g., in the third direction D3) to draw out a wire, moving the capillary in the first direction to extend the wire, and lowering the capillary in a vertical direction to extend the wire. The moving of the capillary in the first direction D1 may include moving along a curve, for example, along an inverted U shape.

The attaching of the end of the wire to the second chip pad 135 of the third semiconductor chip 130 may be performed by applying heat and/or ultrasonic energy. The end of the wire and the second chip pad 135 of the third semiconductor chip 130 may be stitch-bonded.

One end BW2_L1 of the second wire BW2 may be in contact with the first chip pad 135 of the third semiconductor chip 130. For example, one end BW2_L1 of the second wire BW2 may have the shape of a round ball, which is capable of being obtained by performing ball bonding. The other end BW2_L2 of the second wire BW2 may be in contact with the second chip pad 135 of the third semiconductor chip 130. For example, the other end BW2_L2 of the second wire BW2 may be formed to have a substantially uniform width and may have a smaller width than the one end BW2_L1 of the second wire BW2_L1. This may be obtained by performing stitch bonding.

Both ends BW2_L1 and BW2_L2 of the second wire BW1 may be formed to be in vertical contact with the chip pads 135 of the third semiconductor chip 130, respectively. The second wire BW2 may extend vertically in the third direction D3 without being inclined at both ends BW2_L1 and BW2_L2, and may have a curved shape at an upper portion thereof. For example, when viewed in a cross-sectional view, the second wire BW2 may have an inverted U shape. As an example, each of the first and second wires BW1 and BW2 may include at least one of gold (Au), silver (Ag), copper (Cu), and platinum (Pt).

FIGS. 9, 10A, and 10B shows the one end BW1_L1 of the first wire BW1 is ball-bonded to the chip pads 115 of the first semiconductor chip 110, and the other end BW1_L2 of the first wire BW1 is stitch-bonded to the chip pads 125 of the second semiconductor chip 120, but is not limited thereto. For example, one end BW1_L1 of the first wire BW1 may be stitch-bonded to the chip pads 115 of the first semiconductor chip 110, and the other end BW1_L2 of the first wire BW1 may be ball-bonded to the chip pads 125 of the second semiconductor chip 120.

As another embodiment, the second wires BW2 may be formed to be in contact with the chip pads 135 and 145 of the third and fourth semiconductor chips 130 and 140. For example, one end BW2_L1 of the second wire BW2 may be ball-bonded to be in contact with the chip pads 135 of the third semiconductor chip 130, and the other end BW2_L2 of the second wire BW2 may be ball-bonded to be in contact with the chip pads 145 of the fourth semiconductor chip 140. According to this embodiment, the chip bump CB may be omitted.

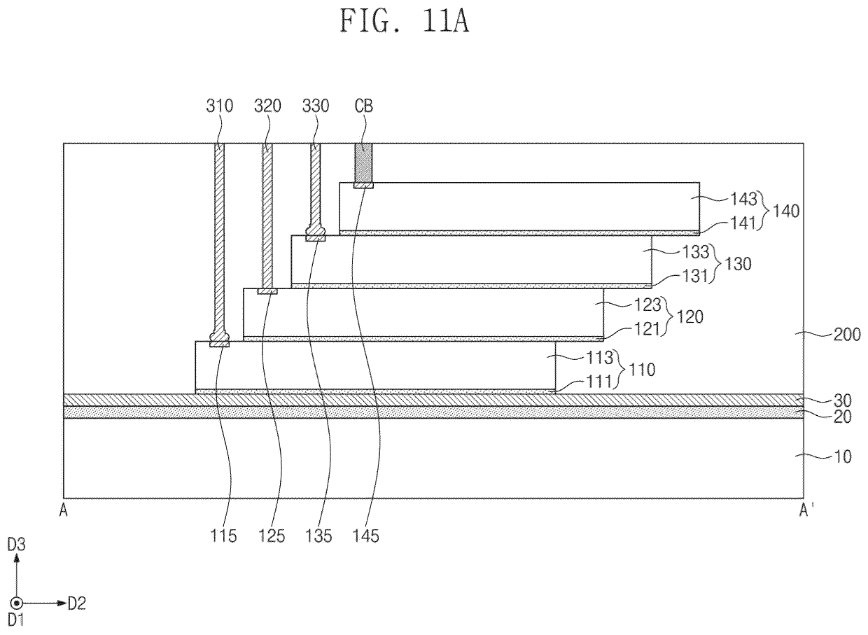

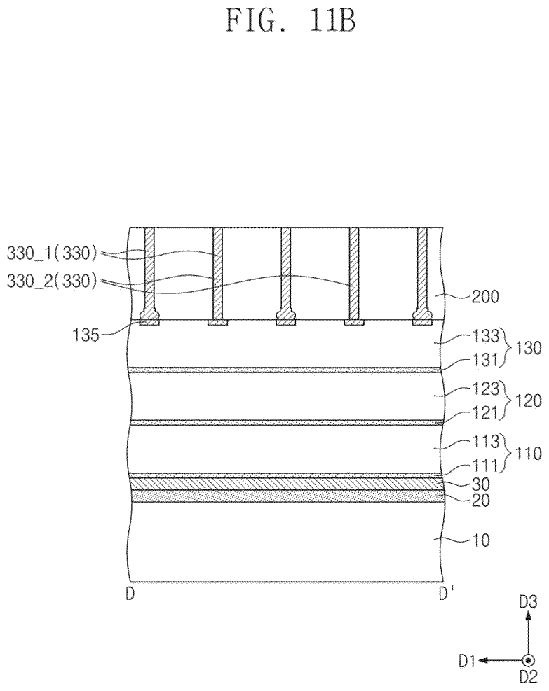

Referring to FIGS. 1, 11A, and 11B, a molding layer 200 may be formed to cover the first and second wires BW1 and BW2 (e.g., in FIG. 10A) and the chip stack 110, 120, 130, and 140.

Thereafter, an upper surface of the chip bump CB may be exposed through a grinding process. In the grinding process, portion of the first and second wires BW1 and BW2 (e.g., in FIG. 10A) may be removed, and thus the first and second bonding wires 310 and 330_1 and the first and second vertical wires 320 and 330_2 may be formed. For example, curved portions of the first and second wires BW1 and BW2 (e.g., in FIG. 10A) may be removed, and the vertically extending portions may remain. As a portion of the first wire BW1 (e.g., in FIG. 10A) is removed, the first wire BW1 (e.g., in FIG. 10A) may be separated into the first bonding wire 310 and the first vertical wire 320. As a portion of the second wire BW2 (e.g., in FIG. 10A) is removed, the second wire BW2 (e.g., in FIG. 10A) may be separated into a second bonding wire 330_1 and a second vertical wire 330_2. Furthermore, upper surfaces of the first and second bonding wires 310 and 330_1, upper surfaces of the first and second vertical wires 320 and 330_2, and upper surfaces of the molding layer 200 may be coplanar with each other.

According to one or more embodiments, the first and second wires BW1 and BW2 (e.g., in FIG. 10A) may extend vertically in the third direction D3 at both ends connected to the chip pads 115, 125, 135, and 145. Furthermore, while forming the molding layer 200, even when the molding layer 200 covers the first and second wires BW1 and BW2 (e.g., in FIG. 10A), the first and second wires BW1 and BW2 (e.g., in FIG. 10A) may maintain the shape thereof under tension. In other words, ends of the first and second wires BW1 and BW2 (e.g., in FIG. 10A) connected to the chip pads 115, 125, 135, and 145 may not be bent and may not generate wire sweep, thereby preventing the wires from being short-circuited and improving electrical reliability of a semiconductor package.

Furthermore, each of the first and second wires BW1 and BW2 (e.g., in FIG. 10A) may form a pair of bonding wires 310 and 330_1 and a vertical wire 320 and 330_2 formed on the chip pads 115, 125, 135 and 145. For example, a first wire BW1 and a second wire BW2 may be formed and then separated to form a pair of bonding wire and a vertical wire respectively formed on the chip pads 115, 125, 135, and 145. For example, the process of placing and bonding each wires for each of the chip pads 115, 125, 135, and 145 may be omitted, thereby improving productivity of the semiconductor package.

Referring again to FIGS. 2A to 2D, a redistribution substrate 400 may be formed on an upper surface of the molding layer 200. The redistribution substrate 400 may be formed by repeatedly performing a process of forming the insulating layer 410 and redistribution patterns 420a and 420b penetrating the insulating layer 410. The forming of the redistribution patterns 420a and 420b may include forming an insulating layer 410, patterning the insulating layer 410 to form an opening, and forming a metal layer that fills the opening and covers the insulating layer 410.

A package connection terminal 500 may be formed on the redistribution substrate 400. The package connection terminal 500 may be connected to the uppermost redistribution pattern 420b disposed.

Thereafter, the carrier substrate 10, adhesive layer 20, and metal layer 30 may be removed. For example, the carrier substrate 10, the adhesive layer 20, and the metal layer 30 may be removed through a planarization process (CMP).

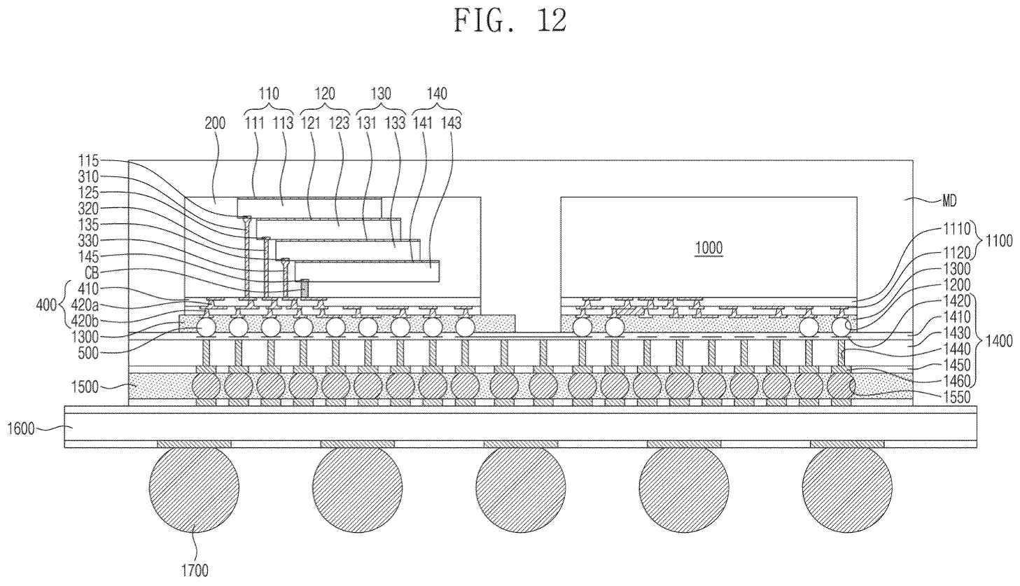

FIG. 12 is a cross-sectional view illustrating a semiconductor package according to one or more embodiments.

Referring to FIG. 12, a semiconductor package may further include a first sub-semiconductor package, a second sub-semiconductor package, an interposer substrate 1400, and a package substrate 1600.

The interposer substrate 1400 may be provided on the package substrate 1600. The interposer substrate 1400 may include a base substrate 1430, a plurality of through electrodes 1440 penetrating the base substrate 1430, an upper insulating layer 1410 on the base substrate 1430, and interconnection patterns 1420 in the upper insulating layer 1410. The interposer substrate 1400 may further include a lower insulating layer 1450 below the base substrate 1430 and external connection members 1460.

The first sub-semiconductor package may be connected to the interposer substrate 1400 through package connection terminals 500. The first sub-semiconductor package may be the semiconductor package described above with reference to FIGS. 1 to 3C. As an example, the first sub-semiconductor package may include package connection terminals 500, a redistribution substrate 400, a molding layer 200, a plurality of bonding and vertical wires 310, 320, and 330, and first to fourth semiconductor chips 110, 120, 130, and 140.

The first sub-semiconductor package may be connected to the interposer substrate 1400 through a second package connection terminal 1200. The second sub-semiconductor package may include a chip structure 1000, a second redistribution substrate 1100, and second package connection terminals 1200. The chip structure 1000 may be a semiconductor package or a semiconductor chip. The chip structure 1000 may be an application specific integrated circuit chip or a system on chip. The chip structure 1000 may also be referred to as a host, an application processor (AP), etc. The chip structure 1000 may be connected to the interposer substrate 1400 through the second package connection terminals 1200 of the second redistribution substrate 1100.

An outer mold layer MD may cover an upper surface of the interposer substrate 1400 and the first and second sub-semiconductor packages. The outer mold layer MD may include an insulating resin such as, for example, epoxy-based molding compound (EMC). The outer mold layer MD may further include a filler, and the filler may be dispersed in the insulating resin. The filler may include, for example, silicon oxide (SiO₂).

The interposer substrate 1400 may be bonded to the package substrate 1600 by third package connection terminals 1550. Fourth package connection terminals 1700 may be bonded to a lower end of the package substrate 1600. The third and fourth package connection terminals 1550 and 1700 may include at least one of a copper bump, a copper pillar, and a solder ball.

A first underfill layer 1300 may be provided between the first sub-semiconductor package and the interposer substrate 1400 and between the second sub-semiconductor package and the interposer substrate 1400. A second underfill layer 1500 may be provided between the interposer substrate 1400 and the package substrate 1600. The first and second underfill layers 1300 and 1500 may be formed through dispensing and curing processes. The first and second underfill layers 1300 and 1500 may include epoxy resin.

In the process of manufacturing the semiconductor package according to one or more embodiments, the U-shaped wire may be disposed to connect the chip pads of the semiconductor chips to each other, and the ends of the wire may be in vertical contact with the chip pads, respectively. Afterwards, when the semiconductor chips and the wire are covered with the molding layer, the wire may maintain the U-shape, which prevents the ends of the wire from bending or causing wire sweep, thereby preventing the wire from short-circuiting. For example, the semiconductor package with the improved electrical reliability may be provided.

Furthermore, one wire may have the U shape and be formed to connect the chip pads of the semiconductor chips to each other. Thereafter, through the process of removing the upper portion of the wire, one wire may be separated into two, and the separated wires may be formed vertically on the chip pads of the semiconductor chip. In other words, by separating one wire, the plurality of wires may be formed on each chip pad, thereby shortening the wire manufacturing process. Accordingly, the productivity of the semiconductor package may be improved.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a chip stack comprising a first semiconductor chip and a second semiconductor chip stacked in a first direction and offset with respect to each other in a second direction intersecting the first direction, each of the first semiconductor chip and the second semiconductor chip comprising chip pads in the second direction;
a redistribution substrate on the chip stack;
first bonding wires connecting the redistribution substrate and the chip pads included in the first semiconductor chip; and
first vertical wires connecting the redistribution substrate and the chip pads included in the second semiconductor chip,
wherein each first bonding wire of the first bonding wires comprising a first portion in contact with one of the chip pads included in the first semiconductor chip and having a first width, and a second portion on the first portion extending in the first direction and having a second width,
wherein each first vertical wire of the first vertical wires has a third width, and
wherein the second width and the third width are smaller than the first width.

2. The semiconductor package of claim 1, wherein each first bonding wire of the first bonding wires further comprising a third portion connecting the first portion and the second portion and having a fourth width, and
wherein the fourth width is smaller than the first width and greater than the second width.

3. The semiconductor package of claim 2, wherein the first portion of each first bonding wire of the first bonding wires has a circular shape when viewed in a top plan view.

4. The semiconductor package of claim 1, wherein the first portion of each first bonding wire of the first bonding wires has a rounded sidewall.

5. The semiconductor package of claim 1, wherein a length of each first bonding wire of the first bonding wires in the first direction is greater than a length of each first vertical wire of the first vertical wires in the first direction.

6. The semiconductor package of claim 1, wherein an upper surface of the second portion is coplanar with an upper surface of the first vertical wire.

7. The semiconductor package of claim 1, wherein the first bonding wires are spaced apart from each other in the second direction and connected to the chip pads included in the first semiconductor chip, and
wherein the first vertical wires are spaced apart from each other in the second direction and are connected to the chip pads included in the second semiconductor chip.

8. The semiconductor package of claim 1, wherein the chip stack further comprises a third semiconductor chip and a fourth semiconductor chip sequentially stacked on the second semiconductor chip in the first direction, each of the third semiconductor chip and the fourth semiconductor chip comprising chip pads in the second direction, and the chip pads included in the third semiconductor chip comprise first chip pads and second chip pads alternately disposed in the second direction,
wherein the semiconductor package further comprises:
a second bonding wire connecting the redistribution substrate and a first chip pad among the chip pads included in the third semiconductor chip;
a second vertical wire connecting the redistribution substrate and a second chip pad among the chip pads included in the third semiconductor chip; and
a chip bump connecting the redistribution substrate and the fourth semiconductor chip,
wherein the second bonding wire comprises a fourth portion in contact with the first chip pad included in the third semiconductor chip and having a fifth width, and a fifth portion extending on the fourth portion extending in the first direction and having a sixth width, and
wherein the sixth width is smaller than the fifth width.

9. The semiconductor package of claim 8, wherein the second vertical wire has a seventh width, and the seventh width is smaller than the fifth width.

10. The semiconductor package of claim 1, wherein the chip stack further comprises a third semiconductor chip and a fourth semiconductor chip sequentially stacked on the second semiconductor chip, each of the third semiconductor chip and the fourth semiconductor chip comprising chip pads in the second direction,
wherein the semiconductor package further comprises:
second bonding wires connecting the redistribution substrate and the chip pads included in the third semiconductor chip; and
second vertical wires connecting the redistribution substrate and the chip pads included in the fourth semiconductor chip,
wherein each of the second bonding wires comprises a fourth portion in contact with one of the chip pads included in the third semiconductor chip and having a fifth width, and a fifth portion on the fourth portion extending in the first direction and having a sixth width, and
wherein the sixth width is smaller than the fifth width.

11. The semiconductor package of claim 10, wherein each second vertical wire of the second vertical wires has a seventh width, and the seventh width is smaller than the fifth width.

12. The semiconductor package of claim 11, wherein the second bonding wires are spaced apart from each other in the second direction and connected to the chip pads included in the third semiconductor chip, and
wherein the second vertical wires are spaced apart from each other in the second direction and are connected to the chip pads included in the fourth semiconductor chip.

13. A semiconductor package comprising:
a chip stack comprising a plurality of semiconductor chips stacked in a first direction and offset from each other in a second direction intersecting the first direction, a first semiconductor chip included in the plurality of semiconductor chips comprising first chip pads and second chip pads alternately in the second direction;
a redistribution substrate on the chip stack;
first bonding wires connecting the first chip pads included in the first semiconductor chip and the redistribution substrate; and
first vertical wires connecting the second chip pads included in the first semiconductor chip and the redistribution substrate,
wherein each first bonding wire of the first bonding wires comprises a first portion in contact with one of the first chip pads included in the first semiconductor chip and having a first width, and a second portion on the first portion extending in the first direction and having a second width,
wherein each of the first vertical wires has a third width, and
wherein the second width and the third width are each smaller than the first width.

14. The semiconductor package of claim 13, wherein each first bonding wire of the first bonding wires further comprises a third portion connecting the first portion and the second portion and having a fourth width in the second direction, and
wherein the fourth width is smaller than the first width and is greater than the second width.

15. The semiconductor package of claim 13, wherein the first portion of each first bonding wire of the first bonding wires has a rounded sidewall.

16. The semiconductor package of claim 13, wherein a length of each first bonding wire of the first bonding wires in the first direction is equal to a length of each first vertical wire of the first vertical wires in the first direction.

17. The semiconductor package of claim 13, wherein an upper surface of the second portion of each first bonding wire of the first bonding wires is coplanar with an upper surface of the first vertical wire.

18. The semiconductor package of claim 13, further comprising a molding layer between the chip stack and the redistribution substrate,
wherein an upper surface of the molding layer is coplanar with an upper surface of the first bonding wires and upper surfaces of the first vertical wires.

19. The semiconductor package of claim 18, wherein the molding layer is on side surfaces of the first bonding wires, side surfaces of the first vertical wires and a side surface of the chip stack.

20. A semiconductor package comprising:
a chip stack comprising a first semiconductor chip, a second semiconductor chip, a third semiconductor chip, and a fourth semiconductor chip stacked in a first direction and offset with respect to each other in a second direction intersecting the first direction, each of the first semiconductor chip, the second semiconductor chip, the third semiconductor chip, and the fourth semiconductor chip comprising chip pads in the second direction intersecting;
a molding layer on the chip stack;
a redistribution substrate on the chip stack and the molding layer;
first bonding wires connecting the redistribution substrate and the chip pads included in the first semiconductor chip;
first vertical wires connecting the redistribution substrate and the chip pads included in the second semiconductor chip;
a second bonding wire connecting the redistribution substrate and a first chip pad among the chip pads included in the third semiconductor chip;
a second vertical wire connecting the redistribution substrate and a second chip pad adjacent to the first chip pad in the second direction among the chip pads included in the third semiconductor chip; and
a chip bump connecting the redistribution substrate and the fourth semiconductor chip,
wherein each of the first bonding wires comprises a first portion in contact with one of the chip pads of the first semiconductor chip and having a first width, and a second portion on the first portion extending in the first direction and having a second width,
wherein each of the first vertical wires has a third width, and
wherein the second width and the third width are smaller than the first width.
